(19) United States
(12) Patent Application Publication
(10) Pub. No.: US 2007/0018504 A1
(43) Pub. Date: Jan. 25, 2007

(54) Short duration variable amplitude high voltage pulse generator

(76) Inventors: Scott Albert Wiener, Mount Horeb, WI (US); Daniel Robert Lenz, Stoughton, WI (US)

Correspondence Address: PERKINS COIE LLP;PATENT-SEA, P.O. BOX 1247, SEATTLE, WA, 98111-1247, US

(21) Appl. No.: 10/575,812

(22) PCT Filed: Oct. 14, 2004
(86) PCT No.: PCT/US04/33821

§ 371 Date: Apr. 14, 2006

Related U.S. Application Data
(60) Provisional application No. 60/510,970, filed on Oct. 14, 2003.

(51) Int. Cl. H03K 3/00

(52) U.S. Cl. 307/108

(57) ABSTRACT

An improved electrical pulse generator incorporating MOSFET components, a programmable high voltage power supply, and a shaping network for generating short duration signals having narrow pulse widths and short rise times.

### FIELD OF THE INVENTION

The invention relates generally to apparata and methods for generating electrical pulses of short duration having high amplitudes, and more specifically to a circuit for generating pulses and modifying pulse amplitudes for charging atoms in an atom probe specimen.

### BACKGROUND OF THE INVENTION

High voltage pulsers are devices that generate short duration electrical signals at amplitudes that generally exceed 24 volts. In general, such signals have pulse widths less than 100 nSec and rise times less than 10 nSec. High voltage pulsers can deliver large amounts of electrical charge to a load(s) over a short time interval.

In atom probe microscopy, pulsers are used to generate voltage potentials sufficient to remove ions from a specimen. The voltage potential consists of a DC component and an AC component consisting of a pulse having an amplitude sufficient to, when added to the DC component, remove ideally one ion. The total voltage is known as the evaporation voltage and must be carefully determined.

The performance of a system designed to remove ions from a specimen is dependent on several factors. It has been recognized that if the DC component is relatively close in magnitude to the evaporation voltage, evaporation between pulses occurs resulting in noise in the data. Conversely, if the DC component value is relatively close to the pulse voltage, then only the most excited species of ions are released and/or the specimen fractures. In either event, the quality of the measurement is degraded.

Average evaporation rate is also an important consideration and should be held constant throughout a test. Evaporation rate is a function of the total electric field induced on the specimen. As the radius of a specimen changes throughout a test, the evaporation rate declines. To maintain the average evaporation rate, the total voltage potential must be increased. In addition, voltage potential must be increased if no ions are collected after a set of pulses and/or when the average number of ions collected per series of pulses drops below a set level. Conversely, if the average number of ions per series of pulses exceeds a predetermined level, the total voltage potential must be decreased. In other words, as the total applied voltage potential varies in one direction or another from the ideal voltage required for evaporation, the voltage potential is adjusted accordingly.

Another important parameter in atom probe microscopy is pulse fraction. Pulse fraction is defined as the pulse amplitude divided by the DC voltage. Maintenance of a constant pulse fraction reduces preferential evaporation of specific atomic species and improves resolution.

Presently, high voltage pulse generators are divided into two categories: those that generate pulses via solid-state components and those that do not. Solid-state pulse generators usually generate pulses by use of semiconductor devices such as Metal-Oxide-Semiconductor Field-Effect Transistors MOSFETs), bipolar transistors (including avalanche transistors and modes), and diodes (e.g. step-recovery diodes), whereas non-solid state pulse generators generally use transmission line effects and/or combinations of resistors, capacitors, inductors and relays. The non-solid state techniques suffer from the disadvantage of non-uniform pulse amplitude due to temperature drift and device tolerance (permissible deviation from a specified value) as well as low pulse rates. Such non-uniformities degrade the performance of the application in which the pulser is being used, such as in an atom probe. In contrast, conventional solid state techniques suffer from the disadvantages of limited slew rate (maximum rate at which output can change), with rise times often being in the 10 to 20 nSec range, and/or pulse repetition rate limitations.

In either case, high voltage pulsers are also often limited in that they generate pulses of fixed voltage: the generated voltage must either be accommodated or attenuated (reduced in amplitude) to a desired level. This is problematic since stepped attenuation of any signal can result in quantization errors associated with finite level transitions. Alternatively, in those prior pulsers where voltage is more easily adjustable, it may nonetheless be difficult to precisely and/or automatically control (e.g., pulse voltage may effectively require manual tracking and adjustment). In atom probes, this imposes limits on operating speed, and precludes the use of sophisticated control algorithms.

The operational frequencies of solid-state pulse generators are also limited by component tolerance and heat dissipation. As the operational frequency of a pulse generator increases, the “on” time of current in network components increases considerably, and limitations on heat dissipation cause components to fail.

Because present day solid-state pulse generators face a number of limiting factors, specimen analysis consumes considerable time. Typically, accurate analysis cannot be completed in less than one week. In addition, atom probe performance coincides directly with the quality of the pulse output by the pulse generator. The pulse generator must therefore be configured to supply such a pulse at a high frequency.

### SUMMARY OF THE INVENTION

Preferred versions of the invention involve a pulser circuit having a selectable RC shaping network for generating short duration electrical pulses at a frequency that heretofore has not been realized in an atom probe. The generated pulses have precise and predetermined rise times and widths, as well as continuously adjustable amplitude.

A microcontroller sends program and trigger signals to circuit components and adjusts the signals to modify the pulse amplitudes as needed. The disclosed circuit incorporates MOSFET components and an RC network to achieve high precision and continuously variable pulse amplitudes up to 2000 Vdc or even greater, rise times less than 3 nSec, and repetition rates of 10 KHz or greater into a 50 ohm load.

The microcontroller-based control system programs a high voltage power supply to generate an output signal having an amplitude that is based upon feedback data, desired pulse amplitude, specimen properties, and/or other data. A MOSFET switch in the network rapidly opens and closes. When opened, the programmable high voltage power supply charges a common node. The MOSFET switch closes for a very short time period, thereby generating a short duration high voltage pulse across a pulse shaping network. The cycle continues and the magnitude of the high voltage output signal is adjusted by the microcontroller.

A digital-to-analog converter (DAC) is preferably implemented to control a high voltage bias circuit hence the amplitude of the high voltage output signal. A DAC provides the circuit with a wide range of use and great accuracy at high repetition rates due to the high voltage biasing technique and associated control.

The circuit preferably includes some impedance termination circuitry to reduce reflections (impedance mismatch at a circuit discontinuity resulting in an “echo” of energy back to the voltage source). Also, high voltage transient suppression at the output protects the network from high voltage arcs feeding back from the aperture to the output of the pulser and onto the MOSFET.

One version of the pulser circuit implements stacked MOSFETs to achieve even higher voltage operation because the voltage can be distributed across each MOSFET, hence increased beyond that of single MOSFET configurations.

The circuit may incorporate a feedback network to further improve operation. Depending on the resultant data (or lack thereof), the pulse shape and amplitude can be dynamically changed.

The high performance atom probe disclosed herein could not be constructed through the application of mathematical formula alone, but would require extensive experimentation.

Further advantages, features, and objects of the invention will be apparent from the following detailed description of the invention in conjunction with the associated drawings.

### BRIEF DESCRIPTION OF THE DRAWINGS

FIG. 1 is a block diagram of a first version of a pulser illustrating concepts of the invention.

FIG. 2 is a schematic view of a variation of the pulser of FIG. 1, wherein select components are duplicated to allow for generation of pulses of greater amplitude.

FIG. 3 is a schematic view of a version of the pulser of FIG. 2.

FIG. 4 is a schematic view showing select components of an atom probe and pulse generator circuit.

### DETAILED DESCRIPTION OF PREFERRED EMBODIMENTS OF THE INVENTION

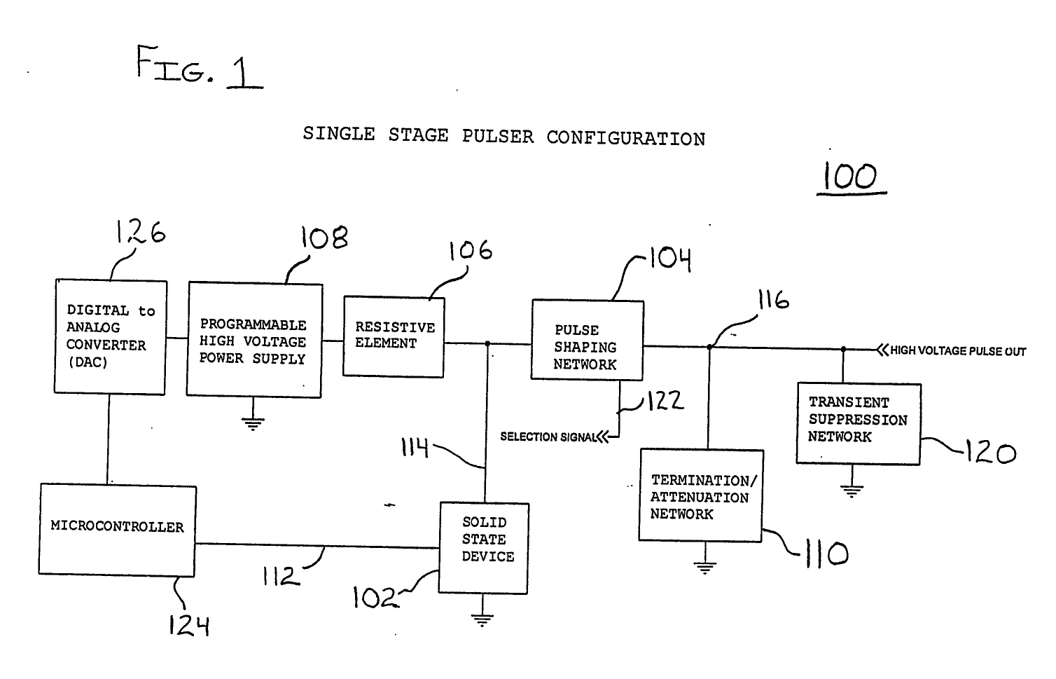

FIG. 1 is a block diagram of one version of a single stage pulser configuration having an RC network. A solid-state device 102 is provided with an input labeled “trigger input”) on line/node 112 and an output on line/node 114 connected to the shaping network 104 and a resistive element 106. Resistive element 106 is connected to a programmable high voltage power supply 108. The reference of the solid state device 102 is connected to ground.

Solid-state device 102 functions as a very fast high voltage switch. When the solid-state device is not saturated, node 114 is charged by the high voltage power supply 108. When a trigger input—which can come from a signal generator, a software controlled gate, or another source—is applied on line/node 112, the solid-state device 102 conducts current and line/node 114 shorts to ground. Heat generated by the circuit may be dissipated through conventional circuit cooling methods.

The high voltage power supply 108 is programmed by the microcontroller 124 to generate a high magnitude voltage. The high voltage power supply 108 continuously charges node 114 as the solid-state switch rapidly opens and closes. The magnitude of the voltage provided by high voltage power supply 108 modulates in accord with microcontroller commands including feedback data (such as ion evaporation) received from the circuit. The voltage modulations are responsive to the changing curvature of the specimen, ion evaporation rate, and other factors.

Resistive element 106 prevents the power supply output 108 from shorting to ground when the solid-state device is “on,” thereby preventing the power supply from limiting its current. In addition, resistive element 106 buffers the output of the high voltage power supply 108 from the load and decouples the pulse from the high voltage power supply 108.

The shaping network 104, whether passive or active, provides pulse coupling and shaping. A passive version of the shaping network 104 may include a combination of resistors, capacitors, inductors and/or diodes, depending on the application. Alternately, the shaping network may include a fixed or variable capacitor. In the preferred version, the shaping network includes a switchable network of capacitors. The network receives a selection signal (which may be software controlled) that controls the configuration of the capacitor components for yielding different pulse shapes. If the shaping network 104 includes one or more capacitors, it is useful to recall that the voltage across a capacitor is equal to the integral of the conducted current divided by the capacitance value:
V=1/C*∫Idt Equation:

Thus, the pulse amplitude at line/node 116 is dependent upon the capacitance value of the shaping network 104 and the voltage at line/node 114. Because the voltage at line/node 114 is dependent upon the voltage output from the programmable high voltage power supply 108—which is in turn dependent on the voltage set at the program voltage input—pulse amplitude is dependent on the program voltage input set by the micro-controller 124.

The combined capacitance of the shaping network 104 and solid state device 102 and the rate at which current flows from the power supply 108 output through the buffer resistor 106 and the high voltage switch 102 determine the maximum allowable pulse frequency. Thus, the capacitance of the shaping network 104 combined with the capacitance of the solid state switch 102 and the magnitude of the buffer resistor 106 determine the time constant at node 114. In addition, the desired width and magnitude of the voltage pulse is dependent upon the capacitance of the shaping network 104. The pulse width may be reduced and magnitude increased by using smaller valued capacitors. The capacitors should be rated to withstand the highest circuit voltages expected under normal operational conditions.

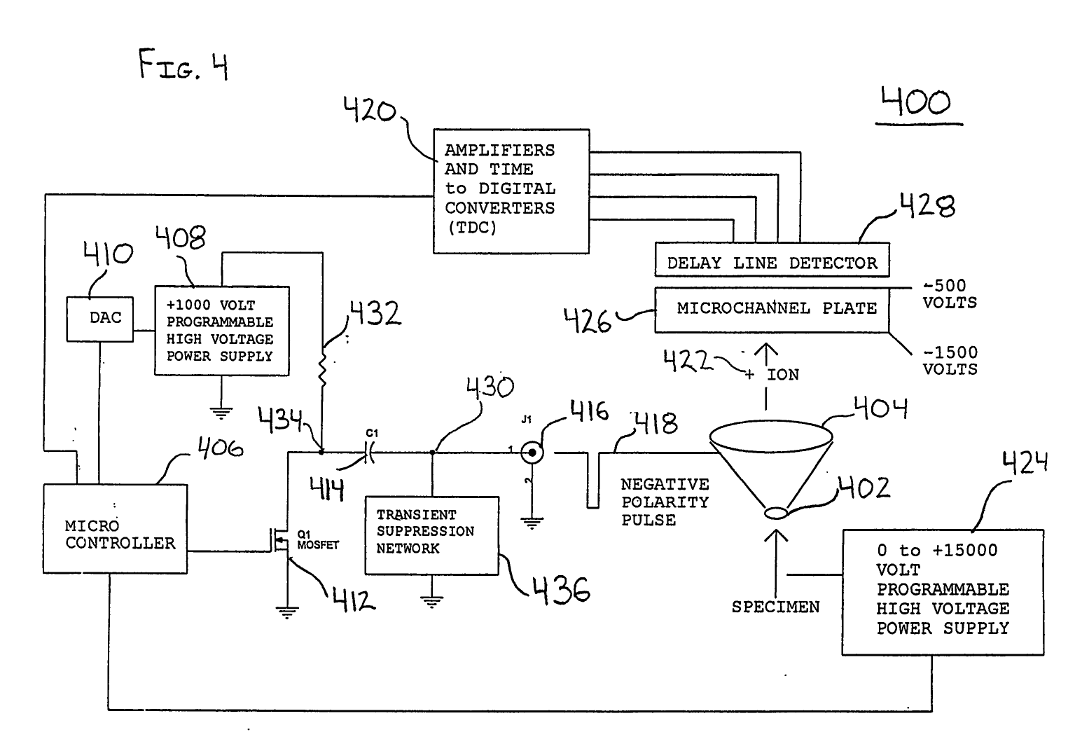

In the preferred version of the invention, a termination/attenuation network 110 is included to perform additional functions. For example, the termination/attenuation network 110 may produce a scaled (attenuated) low voltage “copy” of the output pulse for timing and/or monitoring purposes, e.g., to trigger a timing circuit for triggering of other components, or for monitoring the output pulse shape on the display of an oscilloscope or other device. Alternatively or additionally, the termination/attenuation network 110 can include a passive or active termination network for impedance matching purposes and reduction of artifacts. As an example, careful selection of passive components (resistors, capacitors, diodes and or inductors) can result in a range of impedance matches with the output cable and load, allowing reduction in pulse reflections with a nominal decrease in initial amplitude, and additionally reducing pulse artifacts and associated noise while decreasing the “dead time” between pulses. Alternately, an active termination can be employed, such as a “tail biter” circuit (a high speed switch that shorts to ground after the pulse is generated). A termination network is useful, because a high-speed pulse generator that does not include some form of termination network(s) must usually wait until reflections subside below acceptable limits prior to launching the next pulse, or else it must be tolerant of the reflections. Transient suppression network 120 protects components from potential high voltage arcs generated between the specimen and aperture 404 (FIG. 4).

FIG. 4 is a system diagram showing the preferred arrangement of components in an atom probe 400 having a single stage pulser. A working embodiment of the pulser circuit has been tested and has generated continuously variable pulses having amplitudes over 1000 Vdc into a 50 ohm load, with rise times less than 3 nSec, at greater than 10 kHz, with selectable pulse shaping. The preferred values of the capacitive shaping network, the resistive elements, and solid-state device were derived through extensive experimentation. Preferred parameters for the pulser are provided below, although a pulser having values outside the preferred parameters fall within the description of the pulser.

A specimen 402 is charged by a DC+ high voltage power supply 424. The output node 430 of the pulse generator circuit is connected to a BNC cable 416. The BNC cable 416 is connected to the specimen analysis aperture 404. In this version, the pulse generator provides a negative amplitude pulse 418 to the aperture 404. Having the pulse applied to the aperture instead of the specimen reduces the threat of specimen fracture and reduces specimen length requirements.

The ideal voltage potential between the negative pulse amplitude 418 and the DC+ voltage on the specimen is sufficient to remove one ion 422 from the specimen. The positive ion liberated from the specimen is accelerated by an electric field and impinges upon a negatively charged micro-channel plate (MCP) 426. The MCP converts the ion to an electric cloud. The electron cloud is attracted by the delay line detector 428.

When an electron cloud impacts the delay line, an electromagnetic (EM) pulse is induced in the delay line and propagates as two distinct pulses, one toward each end of the delay line. The amount of time it takes for each pulse to travel to the end of the delay line is proportional to the distance it has traveled, and is therefore proportional to the location the electron pulse hit the delay line. The pulses are amplified and sent to a time-to-digital converter (TDC) 420. The microcontroller 406 determines the location at which the electron cloud collided with the detector by comparing the arrival times of the pulses. The mass-to-charge ratio is determined by comparing the arrival times to the initial transmitted pulse, and the composition of the ion 422 is determined from the mass-to-charge ratio.

Two anodes can be used in the delay line 428. In one version, the anodes are positioned one in front of the other. If the first anode is permeable, some fraction of the electron cloud will fall upon the second anode. In another version, the anodes are placed at a ninety degree angle from one another, providing two-dimensional positional encoding.

In use, the microcontroller 406 determines whether the high voltage power supply 408 output should be increased (if no ion was, detected in the previous period) or decreased (if an ion was detected in the pervious period) and outputs an appropriate signal to the digital-to-analog converter 410, which in turn provides a program voltage signal to the high voltage power supply 408.

The evaporation voltage is established in calibration and maintained throughout the test (unless re-calibration is needed). As the experiment progresses and the pulse amplitude and specimen voltage are adjusted, the pulse fraction can be held constant. A pulse fraction of 20% has proven to be dependable. The microcontroller 406 continues to monitor the evaporation rate and adjusts the pulse frequency accordingly throughout the test.

An atom probe incorporating the pulser network described above has demonstrated a pulse repetition rate that provided, in less than one hour, complete atomic structure data for a specimen. Continuously variable high amplitude voltage pulses were generated at an extraordinary rate. Ideal operational parameters, such as pulse fraction and evaporation rate, were maintained.

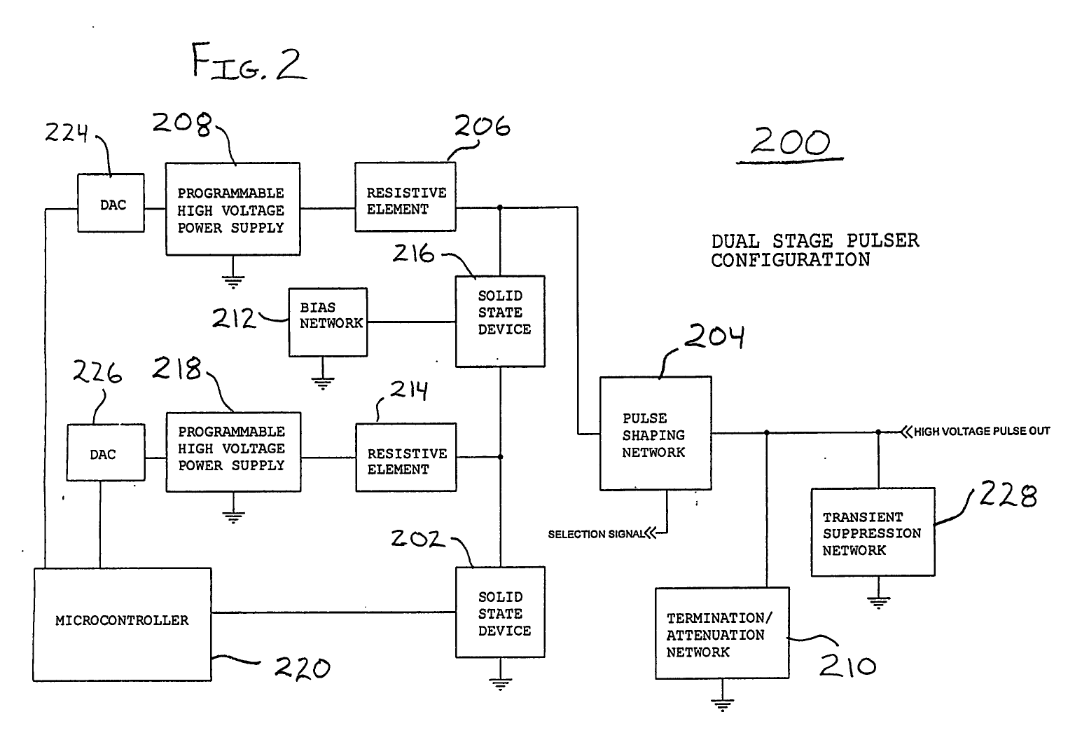

The foregoing design for the invention is readily adaptable for higher voltage operation by stacking solid-state devices, as exemplified by an alternative version of the pulser 200 illustrated in FIG. 2. In the stacked configuration, solid-state devices 202 and 216 are individually biased by respective power supplies, reducing recharge times and therefore increasing pulse repetition rates. In the present version, the circuit includes a second, floating high voltage power supply 208 equivalent to power supply 218. Alternatively, power supply 208 can have a higher rating (for example, pulse amplitude can be doubled if power supply 208 has twice the voltage rating of supply 218). Adding further solid-state devices and high voltage power supplies enable operation in excess of 2000 Vdc. Higher amplitude operation is also obtainable by selecting solid-state devices with higher breakdown voltages (breakdown of dielectric or insulator), and corresponding power supplies having higher capacities.

In the stacked configuration, the input of the solid-state device 216 is maintained in a biased state by network 212, thereby ensuring turn-on of solid state device 216 when solid state device 202 is turned on. The resistive element 206 biases device 216 from the power supply 208.

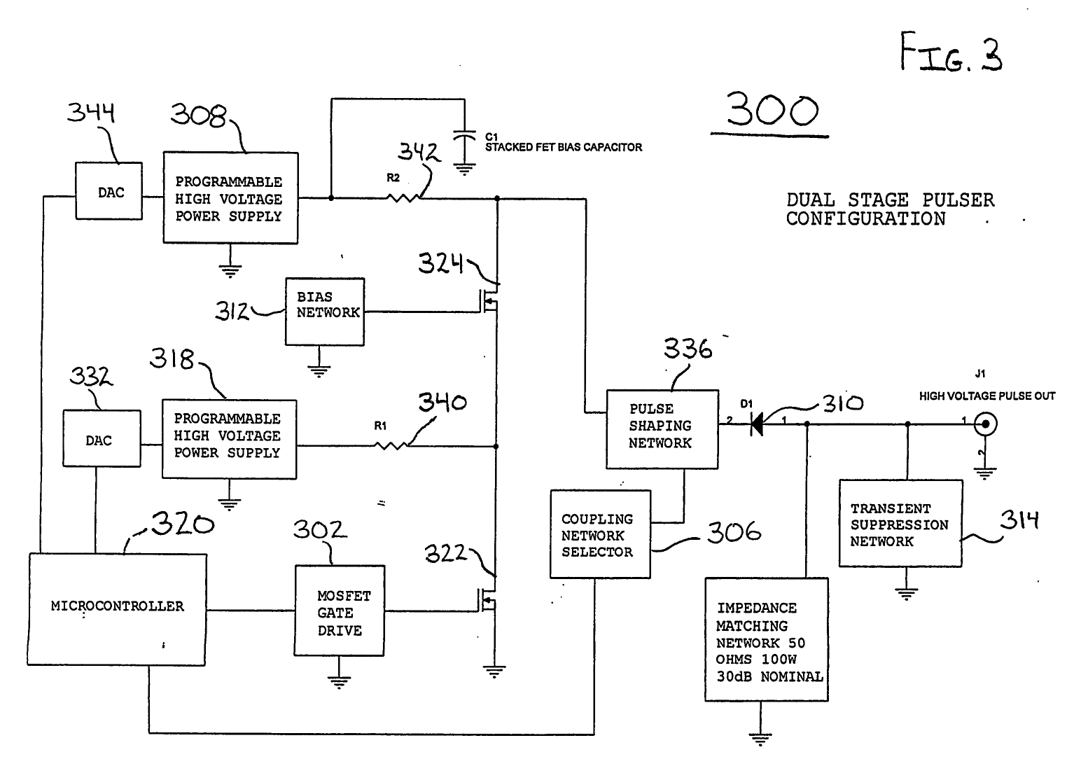

A dual-stacked pulser circuit 300 is shown in FIG. 3. High voltage power supply 308 is connected to the drain of a metal-oxide-semiconductor field-effect transistor (MOSFET) 324 stacked on a MOSFET 322 having a high voltage power supply 318 connected to the drain thereof. Both MOSFETs are rated at 1000 Vdc, and 2 nSec. rise times. The high voltage power supplies are rated at 1000 Vdc, 100 W for 2000 Vdc pulsing at greater than 10 KHz. The pulse shaping network 336 is rated for 2000V operation and could minimally be a capacitor sized for the desired pulse shape (10 pF to 10 nF). Bias resistors 340 and 342 are rated at 200-1000 ohms and 50 Watts.

A gate bias network 312 biases high power switching MOSFET 324. A MOSFET gate drive network 302 drives the gate of high power switching MOSFET 322. The shape of the output signal may be customized/selected under control of coupling network selector 306. An anti-reflection/high speed blocking diode 310 reduces reflections. A software programmable impedance matching network 314 provides selectable output attenuation to optimize the operation of the circuit based upon the desired configuration of the output signal. The impedance matching network 314 is preferably rated at 50Ω, 100 watts (dependent upon the pulse amplitude and frequency), and 30 dB nominal.

If the output signals from an amplifier TDC circuitry (not shown) are not within the desired range, the microcontroller 320 adjusts the program voltage accordingly. Pulse amplitude is adjusted by the microcontroller 320 through a signal sent to the digital-to-analog converter 332 for input to the programmable high voltage power supplies 308 and 318.

The invention usefully allows continuous control of pulse amplitudes by adjusting the program voltage for the associated programmable high voltage power supply. A preferred method involves adjustment of the program voltage via a software-controlled digital-to-analog converter (DAC) 344. The DAC 344 supplies a scaled program voltage to the power supply. The power supply magnifies the program voltage and provides the desired voltage to charge the MOSFET 324 output capacitance and shaping network 336. The high power switch 322, operating at the desired frequency, closes and the circuit discharges. Multiple subsequent pulses can be generated at the same voltage, or their amplitude can be increased or decreased with variation of the program voltage as discussed above.

The circuits of FIGS. 3 and 4 have been constructed for use in atom probe microscopy applications, and have generated pulses into a 50 ohm load having amplitudes up to 2000 V (in accordance with FIG. 3) or up to 1000 V (in accordance with FIG. 4), both at frequencies over 10 KHz with rise times of less than 3 ns. In these versions, the solid state devices are high voltage (1000 Vdc) power MOSFETs with short rise times (<=2 nSec). Power resistors having a value in the range of 400-700 ohms and 120 Watts are used for resistive elements 340, 342 and 432. For operation at up to 2000 Vdc, power supply 308 and 318 are rated at 1000V, 125 W (depending upon the load, trigger width, and shaping capacitors). Within the shaping network 336, coupling capacitors are provided with values ranging from 40 pF to 200 F, and are rated at voltages 2000 Vdc. Impedance matching network 314 is rated at 100 ohms and 50 Watts, and includes a 30 dB attenuated output. Additionally, as faster solid state devices become available, rise times can be reduced.

Continuously controlling pulse amplitude is of particular value in devices such as atom probe microscopes (as described in U.S. Pat. Nos. 5,061,850 and 5,440,124), where the ability to change pulse amplitude voltages “on the fly” optimizes data acquisition and improves accuracy. During operation of an atom probe microscope, the specimen being imaged/analyzed “erodes” as its component atoms are evaporated away (with such evaporation being triggered by high voltage pulses). Owing to this erosion, the shape of the specimen gradually changes, and as a result, pulse amplitudes and shapes that may be optimal at one time may be less suitable at other times. By use of the invention, a baseline or “datum” pulse amplitude may be easily set and maintained, and deviations from the datum amplitude are made as directed. Because the invention supports large changes in field strength at a high rate, non-conductive materials can be analyzed in a relatively short period of time.

Modifying pulse shapes via a shaping network improves results by allowing optimization of pulse shapes for particular specimen material compositions, specimen shapes, etc. During a typical atom probe data acquisition, the voltage between the specimen and electrode generally needs to increase over the duration of the measurement. To maintain a constant pulse fraction the pulse amplitude needs to track the standing voltage. Pulse fraction maintenance and accurate sensing of the voltages involved is crucial to accurate compositional analysis.

It is understood that the invention is not confined to the particular construction and arrangement of parts herein illustrated and described, but embraces such modified forms thereof as come within the scope of the following claims.

What is claimed is:

1. A pulser circuit for generating an electrical pulse of short duration for use in an atom probe, comprising:
(a) a circuit comprising at least a first node;
(b) a voltage supply for charging the first node;
(b) a switching network having a first switch operable between a conductive state for shorting the first node to a grounded node and a nonconductive state for opening the circuit between the first node and the grounded node, and an RC network having a time constant of less than 33 microseconds, comprising at least one resistor connected between the first node and the voltage supply, and wherein the capacitance is a combination of the switch capacitance and at least one capacitor connected to the node, and
(d) wherein the switch is in a nonconductive state to charge the RC network and the switch is in a conductive state to discharge the RC network, thereby generating the electrical pulse.

2. The pulser circuit of claim 1 further comprising a controllable shaping network for providing pulses of selectable amplitudes and shapes.

3. The pulser circuit of claim 1 further comprising at least one switching network connected in series with the RC network

4. The pulser circuit of claim 1 further comprising a shunting network for shunting transients to a low impedance node.

5. A pulser circuit for generating an electrical pulse of short duration for use in an atom probe, comprising:
(a) a circuit comprising at least a first node;
(b) a voltage supply for charging the first node;
(c) a switch operable between a conductive state for shorting the first node to a grounded node and a nonconductive state for opening the circuit between the first node and the grounded node;
(d) a controllable RC network, comprising at least one resistor connected between the first node and the voltage supply, and wherein the capacitance is a combination of the switch capacitance and at least one capacitor connected to the node, for generating pulses having selectable amplitudes and shapes; and
(e) wherein the switch is in a nonconductive state to charge the RC network and the switch is in a conductive state to discharge the RC network, thereby generating the electrical pulse.

6. A pulser circuit for generating an electrical pulse of short duration for use in an atom probe, comprising:
(a) a circuit comprising at least a first node;
(b) a voltage supply for charging the first node;
(c) a first switch operable between a conductive state for shorting the first node to a grounded node and a nonconductive state for opening the circuit between the first node and the grounded node;
(d) an RC network, comprising at least one resistor connected between the first node and the voltage supply, and wherein the capacitance is a combination of the switch capacitance and at least one capacitor connected to the node,
(e) at least one or more second switching networks connected in series;
(f) wherein the switch is in a nonconductive state to charge the RC network and the switch is in a conductive state to discharge the RC network, thereby generating the electrical pulse.
